(19) United States
(12) Patent Application Publication
(10) Pub. No.: US 2005/0142847 A1
(43) Pub. Date: Jun. 30, 2005

(54) Method for forming metal wiring in semiconductor device

(75) Inventor: Hyun Kyu Ryu, Kyungki-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyungki-Do (KR)

(21) Appl. No.: 10/879,785

(22) Filed: Jun. 29, 2004

(30) Foreign Application Priority Data
Dec. 30, 2003 (KR) 2003-100158

(51) Int. Cl. H01L 21/322; H01L 21/4763; H01L 21/44

(52) U.S. Cl. 438/623; 438/643; 438/688

(57) ABSTRACT

The present invention discloses a method for forming metal lines in a semiconductor device. A plurality of metal lines are densely formed by using Al or Al alloy as a material and performing a reactive ion etching process using a low-k dielectric layer as hard mask patterns. Barrier metal layers are formed on the sidewalls of the metal lines. A low dielectric interlayer insulation film is formed when the low dielectric hard mask patterns exist. It is thus possible to obtain margins in a line process and gains in a critical value of the interlayer insulation film for insulating the metal lines. Therefore, a RC delay time can be reduced by restricting crosstalk between the metal lines and decreasing a capacitance between the metal lines.

### BACKGROUND

1. Field of the Invention

The present invention relates to a method for forming metal lines in a semiconductor device, and more particularly to, a method for forming metal lines in a semiconductor device which can reduce an RC delay time by restricting crosstalk between the metal lines and decreasing capacitance between the metal lines, by using a low-k dielectric layer and performing a reactive ion etching (RIE) process.

2. Discussion of Related Art

According to a high integration, high function and miniaturization tendency of a semiconductor device, a material which is advantageous in an RC delay time due to a low specific resistance, and which is highly resistible to electromigration (EM) and stressmigration (SM) is required as a material of metal lines. Instead of Al which has been generally used as the most appropriate material of the metal lines, Cu newly attracts attention.

Cu is used as the material of the metal lines because a melting point of Cu (1080° C.) is relatively higher than that of Al (660° C.) and a specific resistance of Cu (1.7 μΩm) is lower than that of Al (2.7 μΩm).

Efforts have been made to use Cu lines as the metal lines of the semiconductor device in consideration of the excellent characteristics of the Cu lines. However, the Cu lines are hardly dry-etched and easily corroded in air, and Cu atoms are easily diffused into an insulation film. Accordingly, the Cu lines cannot be practically used. In order to overcome the foregoing problems, a single damascene process or a dual damascene process is introduced. In addition, a low-k dielectric layer is used as an interlayer insulation film to prevent increase of capacitance between the metal lines.

Although the Cu lines are formed on the low dielectric interlayer insulation film by the damascene process, as a flash memory device gets shrunken below 120 nm, a space between the adjacent Cu lines and a width of the Cu lines are reduced. As a result, an RC delay time seriously increases due to high crosstalk and capacitance between the Cu lines. Increase of the RC delay time decreases reliability of the device and prevents high integration of the device.

Such problems result from difficulty of the Cu line process. The problems of the general Cu line process will now be explained. Here, the Cu lines are formed as dense as bit lines of the flash memory device, and applied to a high integration device. If the Cu lines are not densely formed and not applied to the high integration device, the above problems do not occur.

Cu lines are formed by forming damascene patterns having trenches (parts on which the lines are formed) and via contact holes (parts electrically connected to a lower conductive layer) on a low dielectric interlayer insulation film by a damascene process, filling Cu in the damascene patterns, and polishing the Cu layer on the interlayer insulation film by a chemical mechanical polishing (CMP) process.

First, a few processes for removing photoresist patterns and a few cleaning processes must be performed until the Cu line process is finished. During the processes, the interlayer insulation film for insulating the Cu lines is etch-lost, and thus a width between the Cu lines is reduced. Accordingly, a critical value of the interlayer insulation film for insulating the Cu lines is not obtained, and thus an RC delay time increases due to high crosstalk and capacitance between the adjacent Cu lines.

Second, when the damascene patterns are small, Cu cannot be regularly filled without pores by a general physical vapor deposition (PVD) or chemical vapor deposition (CVD). Recently, an electro-plating process using a plating solution mixed with an appropriate additive is used to deposit Cu without pores. A Cu seed layer is essential to use the electro-plating process. However, the trenches and the via holes get narrower than a real line width due to the Cu seed layer. It is thus more difficult to regularly fill Cu. In order to solve the above problems, research and development have been made on a plating solution having an excellent filling capability and a method for filling Cu by the CVD.

Third, Cu is easily diffused into an insulation film, and thus a diffusion barrier film for restricting diffusion of Cu must be formed on the circumferences of the Cu lines. A thickness of the diffusion barrier film also needs to be reduced to constantly maintain a bulk ratio of the diffusion barrier film and restrict increase of a specific resistance of the metal lines in reduction of the line width. However, it is difficult to form a thin and uniform diffusion barrier film along the curved surfaces of the trenches and the via contact holes. For this, a deposition method such as atomic layer deposition (ALD) has been investigated. The thinner diffusion barrier film does not normally perform its function. A complete ideal diffusion barrier film would not be developed in the next generation semiconductor device.

Fourth, problems remain in the CMP process essentially performed after depositing the Cu layer by the electroplating process. The CMP process applies mechanical friction and chemical reaction. The interlayer insulation film must be provided with excellent mechanical properties to endure such difficult conditions. However, the low dielectric material used as the interlayer insulation film generally has weak mechanical properties, and thus does not successfully pass through the CMP process. Moreover, a polishing ratio of the CMP process is changed due to different mechanical properties between Cu and the interlayer insulation film, which causes problems in a planarization process. Accordingly, mechanical physical properties of the low dielectric interlayer insulation film must be improved.

As described above, it is apparent that the Cu lines have basic physical properties to be used for the next generation high performance semiconductor device instead of the Al lines. Nevertheless, highly-reliable metal lines cannot be formed merely by replacing Al by Cu because of the aforementioned problems.

### SUMMARY OF THE INVENTION

The present invention is directed to a method for forming metal lines in a semiconductor device which can reduce an RC delay time and form highly reliable metal lines, by restricting crosstalk between the metal lines and decreasing capacitance between the metal lines in the next generation high performance high integration semiconductor device, in spite of using Al or Al alloy having inferior basic physical properties to those of Cu as a material of the metal lines.

One aspect of the present invention is to provide a method for forming metal lines in a semiconductor device, comprising the steps of: forming a metal layer on a semiconductor substrate; forming a low-k dielectric layer on the metal layer; forming a plurality of metal lines by reactive ion etching process using the low-k dielectric layer as a hard mask; forming barrier metal layers on the sidewalls of the metal lines; and forming an interlayer insulation film comprised of a low-k dielectric over the resulting structure on which the barrier metal layers have been formed.

Preferably, the hard mask patterns and the interlayer insulation film are formed by using HOSP, HSQ, SILK™ products, Black Diamond and Nanoglass. Each of the metal lines has a stacked structure of a first barrier metal layer, a line material layer and a second barrier metal layer. The first and second barrier metal layers are formed by using Ti or Ti/TiN, and the line material layer is formed by using Al or Al alloy. The barrier metal layers are formed on the sidewalls of the metal lines, by depositing TiN at a thickness of 100 to 200 Å at a deposition temperature below 500° C. by chemical vapor deposition using TDMAT as a precursor, and performing a blanket etch-back process thereon. An RF process for repeatedly performing deposition and etching is performed during the TiN deposition.

According to another aspect of the present invention, a method for forming metal lines in a semiconductor device includes the steps of: sequentially forming a first barrier metal layer, a line material layer and a second barrier metal layer on a semiconductor substrate on which contact plugs have been formed; forming a plurality of hard mask patterns on the second barrier metal layer; forming a plurality of metal lines, by sequentially etching the second barrier metal layer, the line material layer and the first barrier metal layer by a reactive ion etching process using the hard mask patterns; forming third barrier metal layers on the sidewalls of the metal lines; and forming an interlayer insulation film over the resulting structure on which the third barrier metal layers have been formed.

Preferably, the first and second barrier metal layers are formed by using Ti or Ti/TiN, and the line material layer is formed by using Al or Al alloy. The hard mask patterns and the interlayer insulation film are formed by using low-k dielectrics, such as HOSP, HSQ, SILK™ products, Black Diamond and Nanoglass. The third barrier metal layers are formed on the sidewalls of the metal lines by depositing TiN at a thickness of 100 to 200 Å at a deposition temperature below 500° C. by a chemical vapor deposition using TDMAT as a precursor, and performing a blanket etch-back process thereon. An RF process for repeatedly performing deposition and etching is performed during the TiN deposition.

### BRIEF DESCRIPTION OF THE DRAWINGS

FIGS. 1A to 1E are cross-sectional diagrams illustrating sequential steps of a method for forming metal lines in a semiconductor device in accordance with a preferred embodiment of the present invention.

### DETAILED DESCRIPTION OF PREFERRED EMBODIMENTS

A method for forming metal lines in a semiconductor device in accordance with a preferred embodiment of the present invention will now be described in detail with reference to the accompanying drawings.

In case it is described that one film is disposed on or contacts another film or a semiconductor substrate, one film can directly contact another film or the semiconductor substrate, or the third film can be positioned between them. In the drawings, a thickness or size of each layer may be exaggerated to provide easy and clear explanations. Wherever possible, the same reference numerals will be used throughout the drawings and the description to refer to the same or like parts.

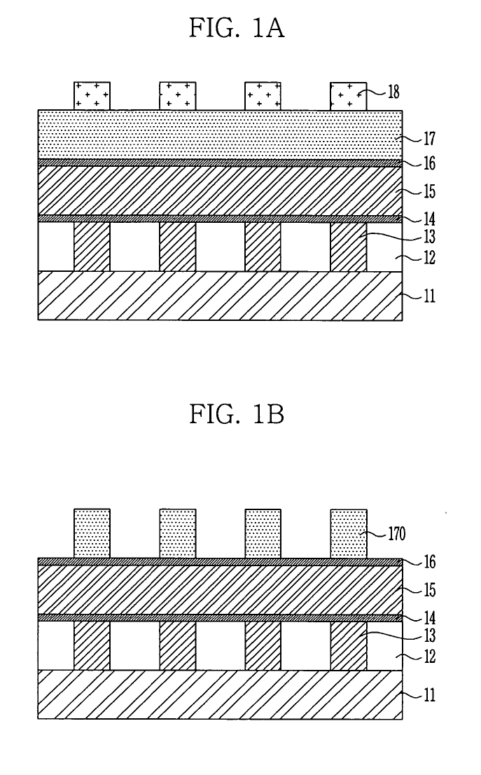

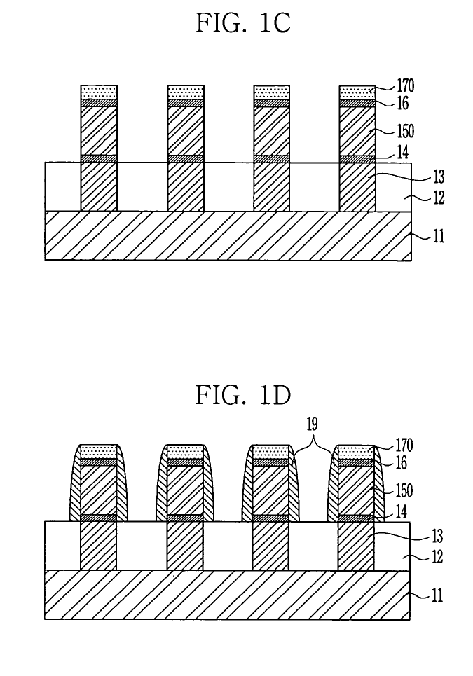

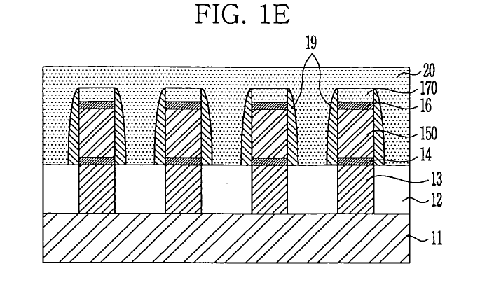

FIGS. 1A to 1E are cross-sectional diagrams illustrating sequential steps of the method for forming the metal lines in the semiconductor device in accordance with the preferred embodiment of the present invention.

Referring to FIG. 1A, a first interlayer insulation film 12 is formed on a substrate 11 on which constitutional elements of the semiconductor device such as a transistor and a memory cell have been formed. A plurality of contact holes are formed by partially etching the first interlayer insulation film 12, and a plurality of contact plugs 13 are formed by filling a contact plug material in the contact holes. A first barrier metal layer 14, a line material layer 15, a second barrier metal layer 16 and a hard mask layer 17 are sequentially formed on the first interlayer insulation film 12 on which the contact plugs 13 have been formed. Photoresist patterns 18 closing presumed metal line regions are formed on the hard mask layer 17.

In the case of a small size of contact holes such as bit line contact holes of a flash memory device below 120 nm, the contact plugs 13 are formed by using W having a relatively higher specific resistance than Al but showing excellent filling properties as a contact plug material. The first and second barrier metal layers 14 and 16 are formed by using Ti or Ti/TiN. The line material layer 15 is formed by using Al or Al alloy which a reactive ion etching (RIE) process is easily applicable to, and which has basic physical properties for the metal lines of the next generation high performance high integration semiconductor device. When a line width of the metal lines and a spatial distance between the metal lines are less than 0.27 μm, a good pattern profile of metal lines cannot be obtained merely by using the photoresist patterns 18 due to difficulty of the RIE process. Therefore, the hard mask layer 17 is used. In order to prevent capacitance from increasing due to a small spatial distance between the metal lines, the hard mask layer 17 is formed at a thickness of 500 to 5000 Å by using a low-k dielectric, for example, HOSP, HSQ, SILK™ products, Black Diamond and Nanoglass.

As illustrated in FIG. 1B, a plurality of hard mask patterns 170 are densely formed in the presumed metal line regions, by removing the exposed parts of the hard mask layer 17 by an etching process using the photoresist patterns 18. The photoresist patterns 18 are removed.

As shown in FIG. 1C, the second barrier metal layer 16, the line material layer 15 and the first barrier metal layer 14 are sequentially etched by the RIE process using the hard mask patterns 170 as an etch mask, to densely form a plurality of metal lines 150 including the first barrier metal layer 14 in their lower ends and the second barrier metal layer 16 in their upper ends. The metal lines 150 can be formed to have a line width and spatial distance below 0.271 μm to be suitable for a high integration device such as a flash memory device below 120 nm. The low dielectric hard mask patterns 170 used as the etch mask in the RIE process are not removed.

As depicted in FIG. 1D, third barrier metal layers 19 are formed on the sidewalls of the metal lines 150. Each of the metal lines 150 is surrounded by the first, second and third barrier metal layers 14, 16 and 19, and thus completely isolated from the outside. That is, the first to third barrier metal layers 14, 16 and 19 prevent the low dielectric layer used as the hard mask patterns 170 and a low dielectric layer which will be used as an interlayer insulation film from directly contacting the metal lines 150. Accordingly, the first to third barrier metal layers 14, 16 and 19 restrict reactivity between the low dielectric layers and the metal lines 150, and increase the width of the metal lines 150, thereby reducing the whole resistance of the metal lines 150.

The third barrier metal layers 19 are respectively formed on the sidewalls of the metal lines 150, by depositing TiN on the surface of the resulting structure including the metal lines 150 at a thickness of 100 to 200 Å by chemical vapor deposition (CVD), and performing a blanket etch-back process thereon to electrically isolate the adjacent metal lines 150. In the case that the metal lines 150 are densely formed in a narrow space of the high integration device such as the flash memory device below 120 nm, the third barrier metal layers 19 are not easily formed on the sidewalls of the metal lines 150. The following process is performed to solve the foregoing problem. First, in order to reduce a thermal budget, TiN is deposited at a thickness of 100 to 200 Å at a deposition temperature below 500° C. by the CVD using tetrakis dimethylamino titanium (TDMAT) as a precursor. Here, TiN is deposited at a thickness of 100 to 200 Å to restrict mutual reactions between the succeeding low dielectric interlayer insulation film and the metal lines 150 and obtain the maximum volume of the low dielectric interlayer insulation film filled in the spaces between the metal lines 150. The deposited TiN is a conductive material electrically connected to the adjacent metal lines 150. So as to simplify the succeeding process for electrically isolating each metal line 150, the thickness of TiN deposited on the space bottoms between the metal lines 150 must be reduced. Therefore, an RF process for repeatedly performing deposition and etching is performed during the TiN deposition, thereby minimizing the thickness of TiN deposited on the space bottoms between the metal lines 150. Thereafter, TiN existing on the space bottoms between the metal lines 150 is removed by a blanket etch-back process, to electrically isolate each metal line 150. As a result, the third barrier metal layers 19 comprised of TiN remain on the side surfaces of the metal lines 150.

Referring to FIG. 1E, a second interlayer insulation film 20 is formed over the resulting structure on which the third barrier metal layers 19 have been formed. In order to reduce capacitance generated due to a small spatial distance between the metal lines 150, the second interlayer insulation film 20 is formed to sufficiently fill the spaces between the metal lines 150, by employing a low-k dielectric, for example, HOSP, HSQ, SILK™ products, Black Diamond and Nanoglass.

As described earlier, in accordance with the present invention, the plurality of metal lines are densely formed by forming the hard mask layer by using the low-k dielectric, and patterning Al or Al alloy by the RIE process. Therefore, the metal lines have a good pattern profile even in the high integration device such as the flash memory device below 120 nm. In addition, it is possible to obtain margins in the line process and gains in a critical value of the interlayer insulation film for insulating the metal lines. Accordingly, an RC delay time can be reduced by restricting crosstalk between the metal lines and decreasing capacitance between the metal lines. Furthermore, the metal lines are completely sealed up by the barrier metal layers comprised of a conductive material, TiN, thereby restricting reactivity between the low dielectric interlayer insulation films and the metal lines. As a result, the low dielectric properties of the interlayer insulation films are maintained, and the width of the metal lines is increased, to reduce the whole resistance of the metal lines.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A method for forming metal lines in a semiconductor device, comprising the steps of:
forming a metal layer on a semiconductor substrate;
forming a low-k dielectric layer on the metal layer;
forming a plurality of metal lines by reactive ion etching process using the low-k dielectric layer as a hard mask;
forming barrier metal layers on the sidewalls of the metal lines; and
forming an interlayer insulation film comprised of a low-k dielectric over the resulting structure on which the barrier metal layers have been formed.

2. The method of claim 1, wherein the hard mask patterns and the interlayer insulation film are formed by using HOSP, HSQ, SILK™ products, Black Diamond and Nanoglass.

3. The method of claim 1, wherein each of the metal lines has a stacked structure of a first barrier metal layer, a line material layer and a second barrier metal layer.

4. The method of claim 3, wherein the first and second barrier metal layers are formed by using Ti or Ti/TiN.

5. The method of claim 3, wherein the line material layer is formed by using Al or Al alloy.

6. The method of claim 1, wherein the barrier metal layers are formed on the sidewalls of the metal lines, by depositing TiN at a thickness of 100 to 200 Å at a deposition temperature below 500° C. by chemical vapor deposition using TDMAT as a precursor, and performing a blanket etch-back process thereon.

7. The method of claim 6, wherein an RF process for repeatedly performing deposition and etching is performed during the TiN deposition.

8. A method for forming metal lines in a semiconductor device, comprising the steps of:
sequentially forming a first barrier metal layer, a line material layer and a second barrier metal layer on a semiconductor substrate on which contact plugs have been formed;
forming a plurality of hard mask patterns on the second barrier metal layer;
forming a plurality of metal lines, by sequentially etching the second barrier metal layer, the line material layer and the first barrier metal layer by a reactive ion etching process using the hard mask patterns;
forming third barrier metal layers on the sidewalls of the metal lines; and
forming an interlayer insulation film over the resulting structure on which the third barrier metal layers have been formed.

9. The method of claim 8, wherein the first and second barrier metal layers are formed by using Ti or Ti/TiN.

10. The method of claim 8, wherein the line material layer is formed by using Al or Al alloy.

11. The method of claim 8, wherein the hard mask patterns and the interlayer insulation film are formed by using low-k dielectric layers, such as HOSP, HSQ, SILK™ products, Black Diamond and Nanoglass.

12. The method of claim 8, wherein the third barrier metal layers are formed on the sidewalls of the metal lines by depositing TiN at a thickness of 100 to 200 Å at a deposition temperature below 500° C. by chemical vapor deposition using TDMAT as a precursor, and performing a blanket etch-back process thereon.

13. The method of claim 12, wherein an RF process for repeatedly performing deposition and etching is performed during the TiN deposition.
